(19) United States
(12) Patent Application Publication
(10) Pub. No.: US 2026/0354101 A1
(43) Pub. Date: Nov. 5, 2026

(54) RADIO FREQUENCY ROD GEOMETRY FOR CONTROLLING IMPEDENCE IN ELECTROSTATIC CHUCK

(71) Applicant: Applied Materials, Inc., Santa Clara, CA (US)

(72) Inventors: Jae Chull Lee, San Jose, CA (US); Hungsen Kang, Hayward, CA (US); Andy Mo, San Jose, CA (US)

(73) Assignee: Applied Materials, Inc., Santa Clara, CA (US)

(21) Appl. No.: 19/194,212

(22) Filed: Apr. 30, 2025

(51) Int. Cl. H10P 72/72; H01J 37/32

(52) U.S. Cl. CPC H10P 72/722; H01J 37/32715; H01J 2237/2007; H01J 2237/332

(57) ABSTRACT

A radio frequency (RF) rod adapted for installation in an electrostatic chuck, the RF rod including a main body defined by central portion, a first terminal portion extending axially from a first end of the central portion, and a second terminal portion extending axially from a second end of the central portion, wherein a diameter of the central portion is greater than diameters of the first terminal portion and the second terminal portion.

### FIELD OF THE DISCLOSURE

Implementations of the present disclosure generally relate to the field of semiconductor processing systems. More specifically, implementations of the present disclosure relate to radio frequency rod geometries for controlling impedance in electrostatic chucks used in semiconductor processing systems.

### BACKGROUND OF THE DISCLOSURE

Electrostatic chucks (ESCs) are widely utilized in semiconductor processing systems for securely holding semiconductor wafers or substrates during various fabrication processes. These processes, which include etching, deposition, and ion implantation, require precise and stable wafer positioning to achieve high levels of accuracy and uniformity in the manufactured devices. ESCs employ an electrostatic force generated by applying a voltage to electrodes embedded within the chuck body to securely clamp the wafer.

To enhance the versatility of ESCs in semiconductor processing systems, radio frequency (RF) energy is often employed to improve plasma generation and control within the processing chamber. RF energy is transmitted to the chuck and, consequently, to the wafer via an RF rod, which serves as a conductive path for RF current. The integration of RF energy into ESC operation enables enhanced process control and uniformity, especially in plasma-based processes. However, the efficient and reliable transmission of RF energy through the ESC is a critical challenge due to impedance mismatches and other factors that can degrade performance.

Impedance control within the ESC is particularly important because it affects the transmission of RF energy and the stability of plasma in a process chamber. Inadequate impedance control can lead to power losses, process inefficiencies, and damage to system components. Additionally, achieving a desired total impedance that balances the requirements of plasma processing and electrostatic clamping force is often complex, requiring precise tuning of the ESC system. Conventional designs of RF rods and associated components often fall short of providing the level of control and customization needed to meet these demanding requirements.

With respect to these and other considerations, the present disclosure is provided.

### BRIEF SUMMARY

This Summary is provided to introduce a selection of concepts in a simplified form. This Summary is not intended to identify key features or essential features of the claimed subject matter, nor is this Summary intended as an aid in determining the scope of the claimed subject matter.

According to an embodiment of the present disclosure, a radio frequency (RF) rod adapted for installation in an electrostatic chuck may include a main body defined by central portion, a first terminal portion extending axially from a first end of the central portion, and a second terminal portion extending axially from a second end of the central portion, wherein a diameter of the central portion is greater than diameters of the first terminal portion and the second terminal portion.

According to another embodiment of the present disclosure, an electrostatic chuck (ESC) assembly may include a chuck body defining a substrate support surface, a stem coupled to an underside of the chuck, an electrode embedded within the chuck body, and a radio frequency (RF) rod electrically coupled to the electrode and extending through the stem. The RF rod may include a main body defined by central portion disposed within the stem, a first terminal portion extending axially from a first end of the central portion and into the chuck body, and a second terminal portion extending axially from a second end of the central portion and out of the stem, wherein a diameter of the central portion is greater than diameters of the first terminal portion and the second terminal portion.

According to another embodiment of the present disclosure, a radio frequency (RF) rod adapted for installation in an electrostatic chuck may include a main body defined by central portion, a first terminal portion extending axially from a first end of the central portion, and a second terminal portion extending axially from a second end of the central portion, wherein a diameter of the central portion is greater than diameters of the first terminal portion and the second terminal portion. The RF rod may further include a coupling portion extending from the main body, the coupling portion including a base extending axially from the first terminal portion, and a neck extending axially from the base, wherein the base has a diameter in a range of 1.1 to 1.3 times the diameter of the central portion, and wherein the neck has a diameter in a range of 0.8 to 1.0 times the diameter of the central portion, wherein the central portion has a length in a range of 0.1 to 0.8 times a total length of the RF rod.

### BRIEF DESCRIPTION OF THE DRAWINGS

The accompanying drawings illustrate exemplary approaches of the present disclosure, including the practical application of the principles thereof, as follows:

FIG. 1 is a schematic cross-sectional view illustrating an electrostatic chuck assembly implemented in a processing chamber in accordance with embodiments of the present disclosure;

FIG. 2 is a side view illustrating a radio frequency rod in accordance with embodiments of the present disclosure;

FIGS. 3A-3D are a series of side views illustrating variations of a radio frequency rod in accordance with embodiments of the present disclosure.

The drawings are not necessarily to scale. The drawings are merely representations, not intended to portray specific parameters of the disclosure. The drawings are intended to depict exemplary embodiments of the disclosure, and thus are not to be considered as limiting in scope. In the drawings, like numbering represents like elements.

### DETAILED DESCRIPTION

Systems and apparatus in accordance with the present disclosure will now be described more fully hereinafter with reference to the accompanying drawings, where embodiments of the systems and apparatus are shown. The systems and apparatus may be embodied in many different forms and are not to be construed as being limited to the embodiments set forth herein. Instead, these embodiments are provided so this disclosure will be thorough and complete, and will fully convey the scope of the systems and apparatus to those skilled in the art.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

Embodiments of the present disclosure facilitate precise control over the total impedance of an electrostatic chuck assembly by simply swapping an RF rod of the ESC assembly for an RF rod having a different geometry (e.g., an RF rod having a central portion with a different diameter and/or a different length relative to other portions of the RF rod). Changes in the impedance of other components of the ESC assembly may therefore be easily and conveniently accommodated without deviating from a target total impedance value. Thus, the efficiency and reliability of semiconductor processing operations may be enhanced by ensuring optimized power transmission and process stability.

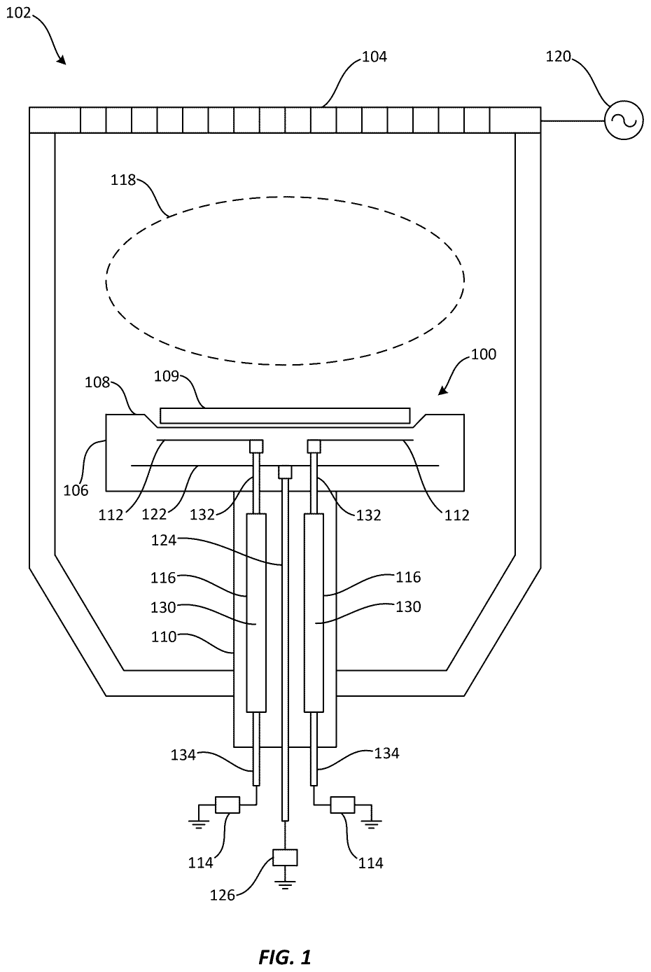

Referring to FIG. 1, a schematic partial cross-sectional view illustrating an exemplary embodiment of an electrostatic chuck assembly 100 (hereinafter “the ESC assembly 100”) in accordance with the present disclosure is shown. For the sake of convenience and clarity, terms such as “top,” “bottom,” “upper,” “lower,” “vertical,” “horizontal,” “lateral,” and “longitudinal” may be used herein to describe the relative position and orientation of various structures and components of the ESC assembly 100, all with respect to the geometry and orientation of such structures and components as they appear in FIG. 1. Said terminology is not intended to be limiting and includes the words specifically mentioned, derivatives thereof, and words of similar import.

The ESC assembly 100 may be adapted for implementation in a processing chamber 102 of a semiconductor processing system. For example, the processing chamber 102 may be a plasma deposition chamber (e.g., an inductively coupled plasma chamber, a decoupled plasma nitridation high dose chamber, etc.) that includes a showerhead 104 located above the ESC assembly 100. The present disclosure is not limited in this regard, and the ESC assembly 100 may be similarly implemented in processing chambers adapted to facilitate other semiconductor manufacturing processes, including, but not limited to, implantation, etching, and cleaning.

The ESC assembly 100 may include a chuck body 106, sometimes referred to as a “puck,” which may include various components embedded therein as further described below. The chuck body 106 may define a substrate support surface 108 upon which a semiconductor substrate or wafer 109 (hereinafter “the substrate 109”) may be disposed. The chuck body 106 and may be characterized by a thickness and length or diameter depending on the specific geometry of the chuck body 106. In some embodiments the chuck body 106 may be elliptical (i.e., when viewed from above) and may be characterized by one or more radial dimensions from a central axis through the chuck body. The present disclosure is not limited in this regard, and the chuck body 106 may have any geometry as may be dictated by a particular application. The ESC assembly 100 may further include a stem 110 coupled to an underside of the chuck body 106. The stem 110 may support the chuck body 106 within the processing chamber 102 and may include various internal channels, conduits, conductors, etc. for supplying electricity and/or fluids to internal components of the chuck body 106 as further described below.

In various embodiments the chuck body 106 and/or the stem 110 may be formed of insulative or dielectric materials. For example, the chuck body 106 and/or the stem 110 may be formed of oxides, nitrides, carbides, or the like. Exemplary materials may include ceramics, including aluminum oxide, aluminum nitride, silicon carbide, tungsten carbide, and any other metal or transition metal oxide, nitride, carbide, boride, or titanate, as well as combinations of these materials and other insulative or dielectric materials. Different grades of ceramic materials may be used to provide composites configured to operate at particular temperature ranges, and thus different ceramic grades of similar materials may be used for the chuck body 106 and the stem 110 in some embodiments. Dopants may be incorporated in some embodiments to adjust electrical properties as well. Exemplary dopant materials may include yttrium, magnesium, silicon, iron, calcium, chromium, sodium, nickel, copper, zinc, or any number of other elements known to be incorporated within a ceramic or dielectric material.

The ESC assembly 100 may further include a one or more electrodes 112 embedded within the chuck body 106 proximate the substrate support surface 108. In various embodiments, the electrodes 112 may be formed of layers of metal mesh. The electrodes 112 may be electrically coupled to respective a DC power sources 114 by respective radio frequency (RF) rods 116 extending through the stem 110. The RF rods 116 may have geometries adapted to facilitate control over a total impedance of ESC assembly 100 as further described below. The power sources 114 may be configured to provide energy or voltage to the electrically conductive electrodes 112. These may be operated to form a plasma from a precursor gas within a processing region 118 of the processing chamber 102, although other plasma operations may similarly be sustained. For example, the electrodes 112 may be chucking meshes that operate as an electrical ground for a capacitive plasma system including an RF source 120 electrically coupled with showerhead 104. The electrodes 112 may operate as a ground path for RF power from the RF source 120, while also operating as an electrical bias to the substrate 109 to facilitate electrostatic clamping of the substrate 109 to the substrate support surface 108. The power source 114 may include filters, power supplies, and a number of other electrical components configured to provide a chucking voltage.

In operation, the substrate 109 may be in at least partial contact with the substrate support surface 108 of the chuck body 106, which may produce a contact gap, and which may produce a capacitive effect between a surface of the chuck body 106 and the substrate 109. Voltage may be applied to the contact gap, which may generate an electrostatic force for chucking. Specifically, the power sources 114 may provide electric charge to the electrodes 112 via the RF rods 116. The charge may migrate from the electrodes 112 to the substrate support surface 108 where it may accumulate and produce a charge layer having Coulomb attraction with opposite charges at the substrate 109, which may electrostatically hold the substrate 109 against the substrate support surface 108. This charge migration may occur by current flowing through the dielectric material of the chuck body 106 based on a finite resistance within the dielectric material for Johnsen-Rahbek type chucking, which may be used in some embodiments of the present technology.

The ESC assembly 100 may further include a heater 122 embedded within the chuck body 106. In various embodiments, the heater 122 may be or may include a resistive heater or a fluid heater adapted to heat the chuck body 106 and the substrate 109 disposed thereon when activated. In some embodiments, the heater 122 may be entirely omitted from the ESC assembly 100, and the electrodes 112 may be operated as heaters. However, by decoupling these operations and providing a separate heater 122, greater individual control may be afforded, and heater coverage within the chuck body 106 may be extended while limiting the region for plasma formation. The heater 122 may be coupled to a power source 124, such as a power source that delivers AC and/or DC current to the heater 122. The power source 124 may be coupled to the heater 122 by one or more rods or wires 126 extending through the stem 110 of the ESC assembly 100. In some embodiments the heater 122 may include multiple heaters, and each heater may be associated with a zone of the chuck body 106.

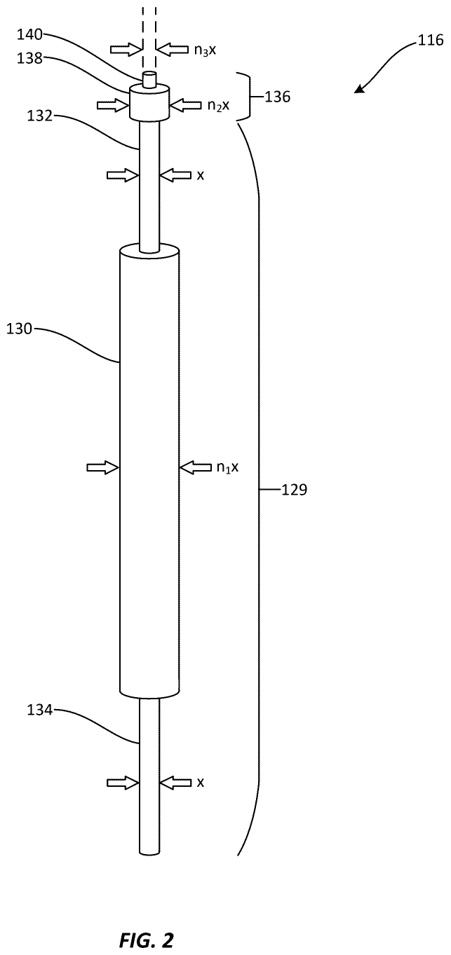

Referring to FIG. 2, a side view illustrating one of the RF rods 116 in isolation is shown. In various embodiments, the RF rod 116 may be formed of a metal with good electrical conductivity, including, and not limited to, copper or aluminum. The RF rod 116 may include a plurality of generally cylindrical, coaxial portions or segments. These portions may include a main body 129 defined by a central portion 130, a first terminal portion 132 extending axially from a top (or first end) of the central portion 130, and a second terminal portion 134 extending axially from a bottom (or second end) of the central portion 130. With reference to FIG. 1, the central portion 130 of the main body 129 may be located entirely within the stem 110 of the ESC assembly 100 while the first terminal portion 132 extends out of a top of the stem 110 into the chuck body 106 and the second terminal portion 134 extends out of a bottom of the stem 110 where it may be coupled to the power source 114. The RF rod 116 may further include a coupling portion 136 that extends axially from a top of the main body 129 (i.e., from the first terminal portion 132) and that is adapted to couple the RF rod 116 to an electrode 112 within the chuck body 106 (see FIG. 1) , such as via brazing, welding, or other suitable techniques. The coupling portion 136 may include a base 138 extending from a top of the first terminal portion 132 and a neck 140 extending from a top of the base 138. In various embodiments, the base 138 may have a larger diameter than the neck 140, and a top surface of the base 138 may flatly abut a bottom of the electrode 112 while the neck 140 extends into a complementary aperture in the electrode 112. The present disclosure is not limited in this regard.

The first terminal portion 132 and the second terminal portion 134 of the main body 129 of the RF rod 116 may be generally equal in diameter. For example, the first terminal portion 132 and the second terminal portion 134 may have a first diameter x, where x may be in a range of 3 millimeters to 5 millimeters. The present disclosure is not limited in this regard. The central portion of the main body 129 may have a diameter that is larger than the diameters of the first terminal portion 132 and the second terminal portion 134. For example, the central portion 130 may have a second diameter n₁x, where n₁ may be in a range of 1.05 to 1.75. That is, the diameter of the central portion 130 may be up to 1.75 times larger than the diameters of the first terminal portion 132 and the second terminal portion 134. The present disclosure is not limited in this regard. The base 138 of the coupling portion 136 of the RF rod 116 may have a third diameter n₂x, where n₂ may be in a range of 1.1 to 1.3, and the neck 140 of the coupling portion 136 may have a fourth diameter n₃x, where n₃ may be in a range of 0.8 to 1.0. The present disclosure is not limited in this regard.

The enlarged central portion 130 of the main body 129 is to be contrasted with traditional RF rod configurations, which include main bodies having a single, uniform diameter. By enlarging the central portion 130 of the main body 129 relative to the first and second terminal portions 132, 134, the surface area and the RF conductivity of the RF rod 116 may be increased (relative to traditional RF rods) while the relatively smaller diameters of the first and second terminal portions 132, 134 may still adhere to dimensional constraints necessary for allowing such portions to interface with components above and below the stem 110. Thus, by selecting an RF rod 116 having a central portion with an appropriate second diameter n₁x, the impedance of the RF rod 116 may be varied (e.g., reduced with a larger diameter), which in-turn allows a total impedance of the ESC assembly 100 to be varied/controlled so that a desired target impedance can be obtained.

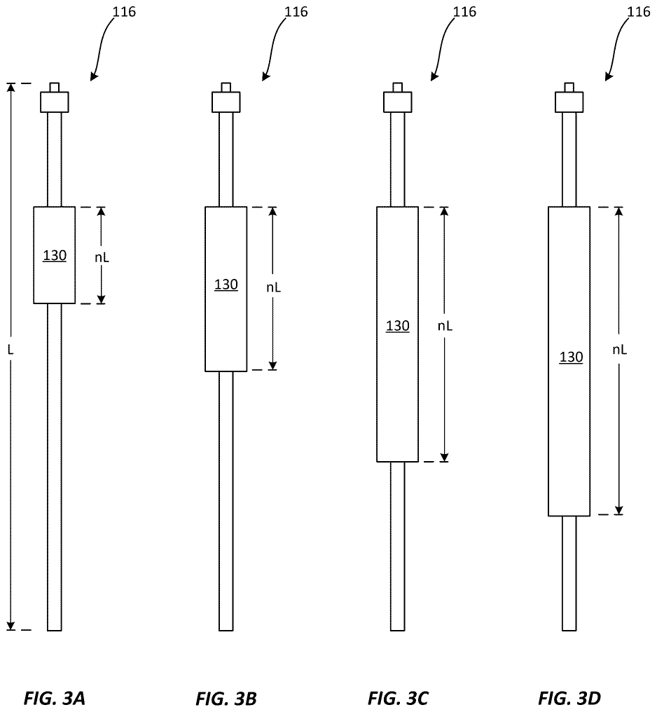

In addition to varying the diameter of the central portion 130 of the main body 129 of the RF rod 116 to control the impedance of the RF rod 116 (and thus the total impedance of the ESC assembly 100), the length of the central portion 130 may also be varied to influence the impedance of the RF rod 116. For example, if the RF rod 116 has a total length L, the central portion 130 may have a length nL, where n may be in a range of 0.1 to 0.8. Referring to FIGS. 3A-3D, examples of RF rods 116 having central portions 130 of various lengths are shown. In FIG. 3A, the central portion 130 portion may have a length nL, where n may have a value of approximately 0.15. In FIG. 3B, n may have a value of approximately 0.25. In FIG. 3C, n may have a value of approximately 0.5. In FIG. 3D, n may have a value of approximately 0.75. It will be understood that the aforementioned values are provided by way of example only, and that that such values are not intended to be limiting. Varying the length of the central portion 130 in addition to increasing the diameter of the central portion 130 relative to the first and second terminal portions 132, 134 may provide greater control over the impedance of the RF rod 116 and thus the total impedance of the ESC assembly 100.

In view of the foregoing, those of skill in the art will appreciate several advantages achieved by the embodiments disclosed herein. For example, the embodiments of the present disclosure facilitate precise control over the total impedance of an ESC assembly by simply swapping an RF rod of the ESC assembly for an RF rod having a different geometry (e.g., an RF rod having a central portion with a different diameter and/or a different length). Changes in the impedance of other components of the ESC assembly may therefore be easily and conveniently accommodated without deviating from a target total impedance value. Thus, the efficiency and reliability of semiconductor processing operations may be enhanced by ensuring optimized power transmission and process stability.

While certain embodiments of the disclosure have been described herein, the disclosure is not limited thereto, as the disclosure is as broad in scope as the art will allow and the specification may be read likewise. Therefore, the above description is not to be construed as limiting. Those skilled in the art will envision other modifications within the scope and spirit of the claims appended hereto.

1. A radio frequency (RF) rod adapted for installation in an electrostatic chuck, the RF rod comprising:
a main body defined by a central portion, a first terminal portion extending axially from a first end of the central portion, and a second terminal portion extending axially from a second end of the central portion;
wherein a diameter of the central portion is greater than diameters of the first terminal portion and the second terminal portion.

2. The RF rod of claim 1, wherein the diameter of the central portion is up to 1.75 times the diameters of the first terminal portion and the second terminal portion.

3. The RF rod of claim 1, further comprising a coupling portion extending from the main body, the coupling portion comprising:
a base extending axially from the first terminal portion; and
a neck extending axially from the base;
wherein the base has a diameter in a range of 1.1 to 1.3 times the diameter of the central portion, and wherein the neck has a diameter in a range of 0.8 to 1.0 times the diameter of the central portion.

4. The RF rod of claim 1, wherein the central portion has a length in a range of 0.1 to 0.8 times a total length of the RF rod.

5. The RF rod of claim 1, wherein the central portion, the first terminal portion, and the second terminal portion are cylindrical and coaxial.

6. The RF rod of claim 1, wherein the RF rod is formed of one of copper and aluminum.

7. The RF rod of claim 1, wherein the first terminal portion and the second terminal portion have diameters in a range of 3 millimeters to 5 millimeters.

8. An electrostatic chuck (ESC) assembly comprising:
a chuck body defining a substrate support surface;
a stem coupled to an underside of the chuck;
an electrode embedded within the chuck body; and
a radio frequency (RF) rod electrically coupled to the electrode and extending through the stem, the RF rod comprising:
a main body defined by central portion disposed within the stem, a first terminal portion extending axially from a first end of the central portion and into the chuck body, and a second terminal portion extending axially from a second end of the central portion and out of the stem;
wherein a diameter of the central portion is greater than diameters of the first terminal portion and the second terminal portion.

9. The ESC of claim 8, wherein the diameter of the central portion is up to 1.75 times the diameters of the first terminal portion and the second terminal portion.

10. The ESC of claim 8, further comprising a coupling portion extending from the main body and coupled to the electrode, the coupling portion comprising:
a base extending axially from the first terminal portion; and
a neck extending axially from the base;
wherein the base has a diameter in a range of 1.1 to 1.3 times the diameter of the central portion, and wherein the neck has a diameter in a range of 0.8 to 1.0 times the diameter of the central portion.

11. The ESC of claim 8, wherein the central portion has a length in a range of 0.1 to 0.8 times a total length of the RF rod.

12. The ESC of claim 8, wherein the central portion, the first terminal portion, and the second terminal portion are cylindrical and coaxial.

13. The ESC of claim 8, wherein the RF rod is formed of one of copper and aluminum.

14. The ESC of claim 8, wherein the first terminal portion and the second terminal portion have diameters in a range of 3 millimeters to 5 millimeters.

15. The ESC of claim 8, wherein an entirety of the central portion is disposed within the stem.

16. The ESC of claim 8, wherein the electrode facilitates electrostatic clamping of a semiconductor substrate to the substrate support surface.

17. A radio frequency (RF) rod adapted for installation in an electrostatic chuck, the RF rod comprising:
a main body defined by central portion, a first terminal portion extending axially from a first end of the central portion, and a second terminal portion extending axially from a second end of the central portion, wherein a diameter of the central portion is greater than diameters of the first terminal portion and the second terminal portion; and
a coupling portion extending from the main body, the coupling portion comprising:
a base extending axially from the first terminal portion; and
a neck extending axially from the base;
wherein the base has a diameter in a range of 1.1 to 1.3 times the diameter of the central portion, and wherein the neck has a diameter in a range of 0.8 to 1.0 times the diameter of the central portion;
wherein the central portion has a length in a range of 0.1 to 0.8 times a total length of the RF rod.

18. The RF rod of claim 17, wherein the central portion, the first terminal portion, and the second terminal portion are cylindrical and coaxial.

19. The RF rod of claim 17, wherein the RF rod is formed of one of copper and aluminum.

20. The RF rod of claim 17, wherein the first terminal portion and the second terminal portion have diameters in a range of 3 millimeters to 5 millimeters.
